(19) United States
(12) Patent Application Publication
(10) Pub. No.: US 2024/0297193 A1
(43) Pub. Date: Sep. 5, 2024

(54) IMAGE SENSOR AND METHOD FOR FORMING THE SAME

(71) Applicant: VisEra Technologies Company Limited, Hsin-Chu City (TW)

(72) Inventors: Wei-Lung TSAI, Hsin-Chu City (TW); Ching-Chiang WU, Hsin-Chu City (TW)

(21) Appl. No.: 18/176,854

(22) Filed: Mar. 1, 2023

(51) Int. Cl. H01L 27/146

(52) U.S. Cl. CPC H01L 27/1463; H01L 27/14621; H01L 27/14629; H01L 27/14636; H01L 27/14685

(57) ABSTRACT

An image sensor is provided. The image sensor includes a substrate and an isolation structure disposed over the substrate. The isolation structure has isolation segments in a cross-sectional view and is electrically non-conductive, and the isolation segments form concave tanks that define pixel regions. The image sensor also includes bottom electrodes disposed at bottoms of the concave tanks and reflective layers disposed on sidewalls of the concave tanks. The image sensor further includes a photoelectric conversion layer disposed on the isolation structure and in the concave tanks and a top electrode disposed on the photoelectric conversion layer. Moreover, the image sensor includes an encapsulation layer disposed on the top electrode.

### BACKGROUND OF THE INVENTION

### Field of the Invention

The present invention relates to an image sensor, and, in particular, to an image sensor that includes reflective layers on sidewalls of the concave tanks of the isolation structure and a method for forming the same.

### Description of the Related Art

Image sensors (e.g., charge-coupled device (CCD) image sensors, complementary metal-oxide semiconductor (CMOS) image sensors, and so on) have been widely used in various image-capturing apparatuses such as digital still-image cameras, digital video cameras, and the like. The light-sensing portion in the image sensor may be formed at each of pixels, and signal electric charges may be generated according to the amount of light received in the light-sensing portion. In addition, the signal electric charges generated in the light-sensing portion may be transmitted and amplified, whereby an image signal is obtained.

Recently, the trend has been for the pixel size of image sensors typified by CMOS image sensors to be reduced for the purpose of increasing the number of pixels per unit area so as to provide high-resolution images. However, while pixel size continues to decrease, there are still various challenges in the design and manufacturing of image sensors. For example, it is difficult for wide-angle incident light to be absorbed by existing image sensors. Moreover, optical cross-talk among pixels will be a serious problem with smaller pixel sizes, and this may have an adverse influence on the performance of the image sensors. New manufacturing techniques are also needed to further decrease the pixel size without leading to serious optical cross-talk among pixels. Therefore, these and related issues need to be addressed by improving the design and manufacture of image sensors.

### BRIEF SUMMARY OF THE INVENTION

According to the present disclosure, an image sensor that includes reflective layers on sidewalls of the concave tanks of the isolation structure is provided. Wide-angle incident light may be blocked in the concave tank to be transported into the corresponding pixel and may be prevented from reaching the neighbor pixel, so that optical cross-talk among pixels may be effectively improved. Moreover, charge carrier absorption may be increased duo to the reflective layers on sidewalls of the concave tanks, thereby increasing sensitivity of the image sensor.

An embodiment of the present invention provides an image sensor. The image sensor includes a substrate and an isolation structure disposed over the substrate. The isolation structure has isolation segments in a cross-sectional view and is electrically non-conductive, and the isolation segments form concave tanks that define pixel regions. The image sensor also includes bottom electrodes disposed at bottoms of the concave tanks and reflective layers disposed on sidewalls of the concave tanks. The image sensor further includes a photoelectric conversion layer disposed on the isolation structure and in the concave tanks and a top electrode disposed on the photoelectric conversion layer. Moreover, the image sensor includes an encapsulation layer disposed on the top electrode.

In some embodiments, the reflective layers include a conductive material.

In some embodiments, the reflective layers include the same material as the bottom electrodes.

In some embodiments, the included angle between each bottom electrode and the corresponding reflective layer in the cross-sectional view is between 90° and 135°.

In some embodiments, the thickness of the reflective layers is greater than or equal to 20 nm.

In some embodiments, the maximum width the concave tank in the cross-sectional view is greater than or equal to 100 nm.

In some embodiments, the maximum width of the isolation segment in the cross-sectional view is greater than or equal to 100 nm.

In some embodiments, the height of the isolation segment in the cross-sectional view is greater than or equal to 50 nm.

In some embodiments, portions of the bottom electrodes extend into bottoms of the isolation segments.

In some embodiments, the top surface of the reflective layer is aligned with or lower than the topmost surface of the corresponding isolation segment.

In some embodiments, the image sensor further includes condensing structures disposed above the encapsulation layer. Each condensing structure corresponds to one pixel region.

In some embodiments, the image sensor further includes a color filter layer disposed between the encapsulation layer and the condensing structures.

In some embodiments, the color filter layer has color filter segments in the cross-sectional view, and the color filter segments correspond to the concave tanks.

In some embodiments, the color filter segments capture different color information.

In some embodiments, the image sensor further includes a circuit layer disposed between the substrate and the isolation structure. The bottom electrodes are electrically connected to the circuit layer.

An embodiment of the present invention provides a method for forming an image sensor. The method for forming the image sensor includes the following steps. An isolation structure is formed over a substrate. The isolation structure has isolation segments in a cross-sectional view and is electrically non-conductive, and the isolation segments form concave tanks. Bottom electrodes are formed at bottoms of the concave tanks.

Reflective layers are formed on sidewalls of the concave tanks. A photoelectric conversion layer is formed on the isolation structure and in the concave tanks. A top electrode is formed on the photoelectric conversion layer. An encapsulation layer is formed on the top electrode.

In some embodiments, forming the bottom electrodes and the reflective layers includes the following steps. A first conductive layer is formed over the substrate. The first conductive layer is patterned to form the bottom electrodes and holes between the bottom electrodes. The isolation structure is formed from the holes to form the concave tanks that define pixel regions.

In some embodiments, forming the bottom electrodes and the reflective layers further includes the following steps. A second conductive layer is formed on the isolation structure. A portion of the second conductive layer on the topmost surface of the isolation structure is removed to form the reflective layers on sidewalls of the concave tanks.

In some embodiments, forming the bottom electrodes and the reflective layers includes the following steps. A cover layer is formed on the isolation structure. The cover layer is disposed on the bottoms and sidewalls of the concave tanks and the topmost surface of the isolation structure. A portion of the cover layer on the topmost surface of the isolation structure is removed to form the bottom electrodes at the bottoms of the concave tanks and the reflective layers on the sidewalls of the concave tanks.

In some embodiments, the method for forming the image sensor further includes the following step. Condensing structures are formed above the encapsulation layer, and each condensing structure corresponds to one pixel region.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 is a cross-sectional view illustrating a portion of the image sensor at one stage in the manufacturing of the image sensor in accordance with some embodiments of the present disclosure.

FIG. 2 is a cross-sectional view illustrating a portion of the image sensor at one stage in the manufacturing of the image sensor in accordance with some embodiments of the present disclosure.

FIG. 3 is a cross-sectional view illustrating a portion of the image sensor at one stage in the manufacturing of the image sensor in accordance with some embodiments of the present disclosure.

FIG. 4 is a cross-sectional view illustrating a portion of the image sensor at one stage in the manufacturing of the image sensor in accordance with some embodiments of the present disclosure.

FIG. 5 is a cross-sectional view illustrating a portion of the image sensor at one stage in the manufacturing of the image sensor in accordance with some embodiments of the present disclosure.

FIG. 6 is a cross-sectional view illustrating a portion of the image sensor at one stage in the manufacturing of the image sensor in accordance with some embodiments of the present disclosure.

FIG. 7 is a cross-sectional view illustrating a portion of the image sensor at one stage in the manufacturing of the image sensor in accordance with some embodiments of the present disclosure.

FIG. 8 is a cross-sectional view illustrating a portion of the image sensor at one stage in the manufacturing of the image sensor in accordance with some embodiments of the present disclosure.

FIG. 9 is a cross-sectional view illustrating a portion of the image sensor at additional stages in the manufacturing of the image sensor in accordance with some other embodiments of the present disclosure.

FIG. 10 is a cross-sectional view illustrating a portion of the image sensor at one stage in the manufacturing of the image sensor in accordance with some other embodiments of the present disclosure.

FIG. 11 is a cross-sectional view illustrating a portion of the image sensor at one stage in the manufacturing of the image sensor in accordance with some other embodiments of the present disclosure.

FIG. 12 is a cross-sectional view illustrating a portion of the image sensor at one stage in the manufacturing of the image sensor in accordance with some other embodiments of the present disclosure.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures.

The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

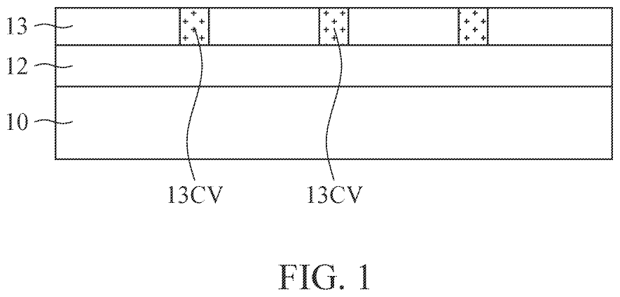

FIG. 1 to FIG. 8 are cross-sectional views illustrating a portion of the image sensor 100 at various stages in the manufacturing of the image sensor 100 in accordance with some embodiments of the present disclosure. It should be noted that some components of the image sensor 100 have been omitted in FIG. 1 to FIG. 8 for the sake of brevity.

Referring to FIG. 1, in some embodiments, a circuit layer 12 is formed on a substrate 10. The substrate 10 may be, for example, a wafer or a chip, but the present disclosure is not limited thereto. The substrate 10 may be a semiconductor substrate, for example, silicon substrate. Furthermore, the semiconductor substrate may also be an elemental semiconductor (e.g., germanium), a compound semiconductor (e.g., gallium nitride (GaN), silicon carbide (SiC), gallium arsenide (GaAs), gallium phosphide (GaP), indium phosphide (InP), indium arsenide (InAs), and/or indium antimonide (InSb)), an alloy semiconductor (e.g., silicon germanium (SiGe) alloy, gallium arsenide phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, and/or gallium indium arsenide phosphide (GaInAsP) alloy), the like, or a combination thereof.

The substrate 10 may include isolation regions (not shown) to separate conductive components formed in the substrate 10. The isolation regions may include, for example, shallow trench isolation (STI) regions or deep trench isolation (DTI) regions. The isolation regions may be formed in the substrate 10 using an etching process to form trenches and filling the trenches with an insulating or dielectric material, but the present disclosure is not limited thereto.

Moreover, the circuit layer 12 may be a readout circuit, which may include various conductive features (e.g., conductive lines or vias). For example, the conductive features may be made of aluminum (Al), copper (Cu), tungsten (W), the like, an alloy thereof, any other applicable conductive material, or a combination thereof, but the present disclosure is not limited thereto.

As shown in FIG. 1, in some embodiments, an isolation layer 13 is formed on the circuit layer 12. For example, the isolation layer 13 may include an electrically non-conductive material, such as silicon nitride, silicon oxide, aluminum oxide, photoresist, other suitable materials, or a combination thereof. The formation of the isolation layer 13 may include using suitable deposition techniques, such as physical vapor deposition (PVD), chemical vapor deposition (CVD), atomic layer deposition (ALD), spin coating, the like, or a combination thereof, but the present disclosure is not limited thereto.

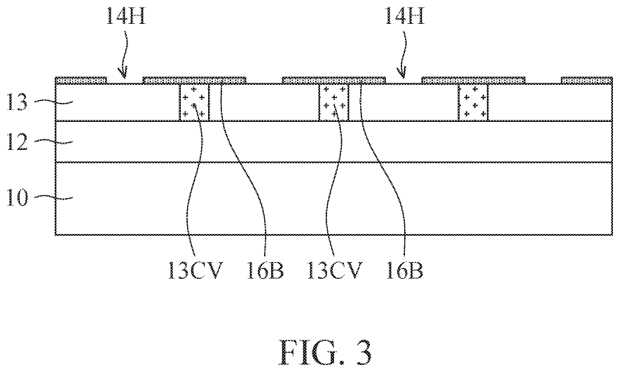

As shown in FIG. 1, in some embodiments, the isolation layer 13 includes contact vias 13CV that may be used to electrically connect the subsequently formed bottom electrodes (e.g., bottom electrodes 16B shown in FIG. 3) to the circuit layer 12. Therefore, the positions of the contact vias 13CV may be determined according to the subsequently formed bottom electrodes, but the present disclosure is not limited thereto.

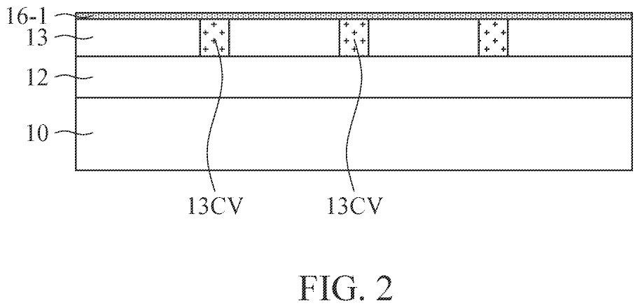

Referring to FIG. 2, in some embodiments, a first conductive layer 16-1 is formed over the substrate 10. In more detail, the first conductive layer 16-1 is formed on the isolation layer 13. For example, the first conductive layer 16-1 may include a conductive material, such as metal, metal silicide, the like, or a combination thereof, but the present disclosure is not limited thereto. The metal may include gold (Au), nickel (Ni), platinum (Pt), palladium (Pd), iridium (Ir), titanium (Ti), chromium (Cr), tungsten (W), aluminum (Al), copper (Cu), the like, an alloy thereof, or a combination thereof, but the present disclosure is not limited thereto. Moreover, the first conductive layer 16-1 may be formed by physical vapor deposition (PVD), chemical vapor deposition (CVD), atomic layer deposition (ALD), evaporation, sputtering, the like, or a combination thereof, but the present disclosure is not limited thereto.

Referring to FIG. 3, in some embodiments, the first conductive layer 16-1 is patterned to form bottom electrodes 16B and holes 14H between the bottom electrodes 16B. For example, a mask layer (not illustrated) may be disposed on the first conductive layer 16-1, and then an etching process may be performed to etch the first conductive layer 16-1 into the bottom electrodes 16B and the holes 14H using the mask layer as an etch mask. The mask layer may include a photoresist, such as a positive photoresist or a negative photoresist. Moreover, the mask layer may be a hard mask and may include silicon oxide (SiO₂), silicon nitride (SiN), silicon oxynitride (SiON), silicon carbide (SiC), silicon carbonitride (SiCN), the like, or a combination thereof, but the present disclosure is not limited thereto.

The mask layer may be a single-layer structure or a multi-layer structure, and may be formed by a deposition process, a photolithography process, any other applicable process, or a combination thereof, but the present disclosure is not limited thereto. For example, the deposition process may include spin-on coating, chemical vapor deposition (CVD), atomic layer deposition (ALD), the like, or a combination thereof. For example, the photolithography process may include photoresist coating (e.g., spin coating), soft baking, mask aligning, exposure, post-exposure baking (PEB), developing, rinsing, drying (e.g., hard baking), other suitable processes, or a combination thereof, but the present disclosure is not limited thereto.

The etching process may include a dry etching process, a wet etching process, or a combination thereof. For example, the dry etching process may include reactive ion etch (RIE), inductively-coupled plasma (ICP) etching, neutral beam etching (NBE), electron cyclotron resonance (ERC) etching, the like, or a combination thereof, but the present disclosure is not limited thereto. For example, the wet etching process may use, for example, hydrofluoric acid (HF), ammonium hydroxide (NH₄OH), or any suitable etchant.

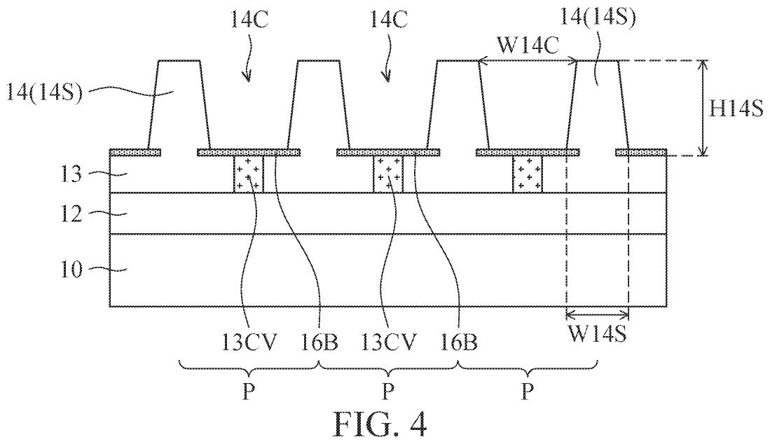

Referring to FIG. 4, in some embodiments, an isolation structure 14 is formed over the substrate 10, and the isolation structure 14 has (or is divided into) isolation segments 14S in a cross-sectional view (e.g. cross-sectional view shown in FIG. 4) and is electrically non-conductive. Moreover, as shown in FIG. 4, in some embodiments, the isolation segments 14S form concave tanks 14C that define pixel regions P. In more detail, the isolation structure 14 is formed from the holes 14H to form the concave tanks 14C that define pixel regions P. In other words, the bottom electrodes 16B are formed at bottoms of the concave tanks 14C, and the circuit layer 12 is disposed between the substrate 10 and the isolation structure 14.

The isolation structure 14 may include the same or similar material as the isolation layer 13. That is, the isolation structure 14 is electrically non-conductive. The formation of the isolation structure 14 may include using suitable deposition techniques, examples of which have been described above and will not be repeated here. After the material for the isolation structure 14 is deposited, photolithography and etching processes are performed to form the isolation structure 14. The cross-sectional profile of the isolation structure 14 may be adjusted by the etching conditions to obtain desired shapes. For example, the isolation structure 14 in the cross-sectional view (i.e., isolation segments 14S) may have a rectangular shape, a trapezoidal shape, an inversely trapezoidal shape, or a triangular shape, but the present disclosure is not limited thereto.

In the embodiment shown in FIG. 4, each isolation segment 14S has a trapezoidal shape. In this embodiment, the maximum width W14S of the isolation segment 14S in the cross-sectional view is greater than or equal to about 100 nm. Here, the maximum width W14S of the isolation segment 14S is the bottommost width of the isolation segment 14S, but the present disclosure is not limited thereto. Moreover, in this embodiment, the height H14S of the isolation segment 14S in the cross-sectional view is greater than or equal to about 50 nm. However, the present disclosure is not limited thereto.

As shown in FIG. 4, in some embodiments, the bottom electrodes 16B extend into bottoms of the isolation segments 14S. Moreover, in some embodiments, each concave tank 14C corresponds to one bottom electrode 16B, and the bottom electrodes 16B are electrically connected to the circuit layer 12 through the contact vias 13CV. That is, the concave tank 14C exposes at least one portion of the corresponding bottom electrode 16B, but the present disclosure is not limited thereto. In the embodiment shown in FIG. 4, the maximum width W14C of each concave tank 14C in the cross-sectional view is greater than or equal to about 100 nm. Here, the maximum width W14C of each concave tank 14C is the topmost width of the each concave tank 14C, but the present disclosure is not limited thereto.

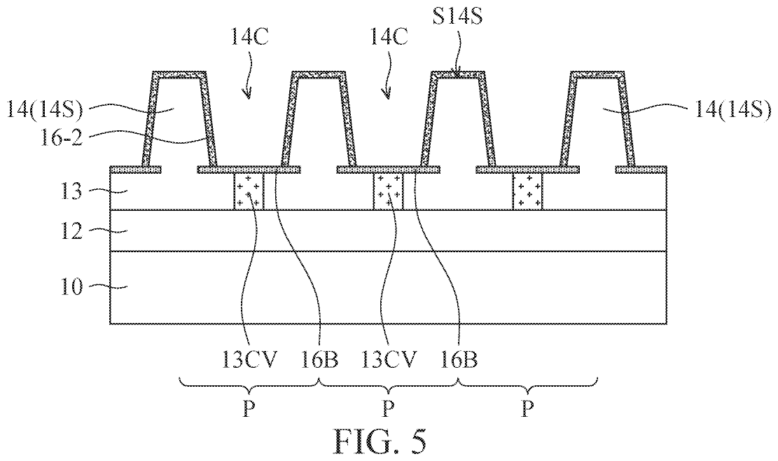

Referring to FIG. 5, in some embodiments, a second conductive layer 16-2 is formed on the isolation structure 14. In more detail, the second conductive layer 16-2 is formed on the topmost surface S14S of the isolation structure 14 (isolation segment 14S) and the sidewalls of the isolation segment 14S (or the sidewalls of the concave tank 14C). For example, the second conductive layer 16-2 may include the same or similar material as the first conductive layer 16-1. In some embodiment, the first conductive layer 16-1 and the second conductive layer 16-2 may include titanium (Ti), titanium nitride (TiN), aluminum (Al), or silver (Ag), but the present disclosure is not limited thereto. In some other embodiments, the first conductive layer 16-1 and the second conductive layer 16-2 are different. Moreover, the formation of the second conductive layer 16-2 may include using suitable deposition techniques, examples of which have been described above and will not be repeated here.

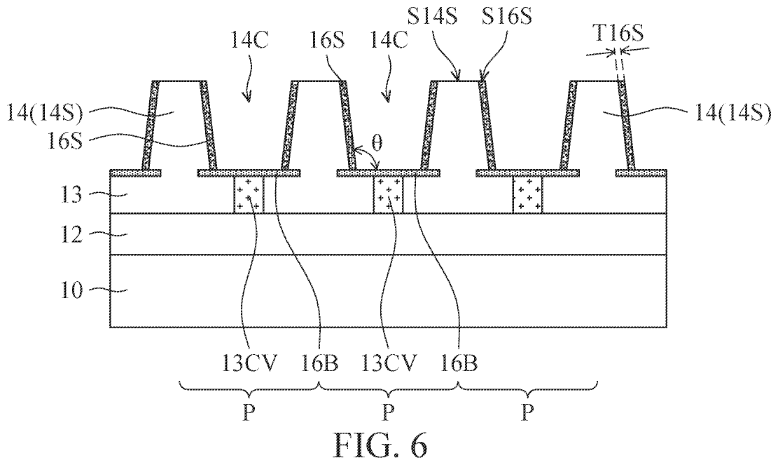

Referring to FIG. 6, in some embodiments, reflective layers 16S are formed on sidewalls of the concave tanks 14C. In this embodiment, a portion of the second conductive layer 16-2 on the topmost surface S14S of the isolation structure 14 is removed to form the reflective layers 16S on the sidewalls of the concave tanks 14C. For example, the portion of the second conductive layer 16-2 on the topmost surface S14S of the isolation structure 14 may be removed by a chemical mechanical polishing (CMP) process, but the present disclosure is not limited thereto. In this embodiment, the reflective layers 16S include a conductive material, and/or the reflective layers 16S include the same material as the bottom electrodes 16B, but the present disclosure is not limited thereto.

As shown in FIG. 6, in some embodiments, the top surface S16S of each reflective layer 16S is aligned with or lower than the topmost surface S14S of the isolation structure 14 (the corresponding isolation segment 14S). That is, the top surface S16S of the reflective layer 16S and the topmost surface S14S of the isolation structure 14 (the isolation segment 14S) may be coplanar, or the top surface S16S of the reflective layer 16S may be lower than the topmost surface S14S of the isolation structure 14 (the isolation segment 14S). Moreover, in some embodiments, the thickness T16S of the reflective layer 16S is greater than or equal to about 20 nm.

In the embodiments of the present disclosure, the reflective layer 16S may be used to reflect light, so that wide-angle incident light may be blocked in the concave tank 14C to be transported into the corresponding pixel region P and may be prevented from reaching the neighbor pixel region P, thereby effectively improving optical cross-talk among pixels. As shown in FIG. 6, in some embodiments, the included angle θ between the bottom electrode 16B and the corresponding reflective layer 16S in the cross-sectional view is between about 90° and about 135°. If the included angle θ is less than 90°, then the subsequently formed photoelectric conversion layer 18 is more difficult to fill in the concave tanks 14C. If the included angle θ is greater than 135°, then optical cross-talk among pixels may not be effectively improved.

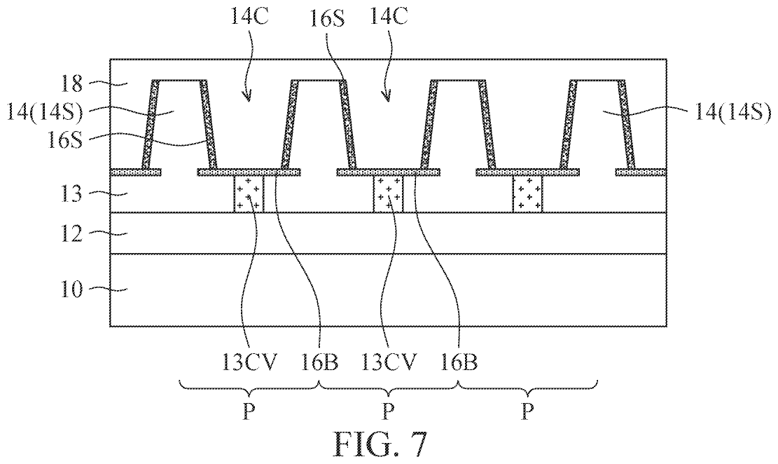

Referring to FIG. 7, in some embodiments, a photoelectric conversion layer 18 is formed on the isolation structure 14 and in the concave tanks 14C. In more detail, the photoelectric conversion layer 18 fills the concave tanks 14C. For example, the photoelectric conversion layer 18 may include a material that absorbs light irradiation and generates signal charges corresponding to an amount of the absorbed light, such as an organic material, a perovskite material, a quantum dots material, any other applicable material, or a combination thereof. The photoelectric conversion layer 18 may be formed by a deposition process, and the deposition process may include spin coating, thermal evaporation, a combination thereof, or the like, but the present disclosure is not limited thereto. Moreover, the photoelectric conversion layer 18 may be planarized with a planarization process, such as a chemical mechanical polishing (CMP) process, but the present disclosure is not limited thereto.

In some embodiments, the photoelectric conversion layer 18 includes an electron transport layer (ETL) or a hole transport layer (HTL). For example, the photoelectric conversion layer 18 may include titanium dioxide (TiO₂), but the present disclosure is not limited thereto.

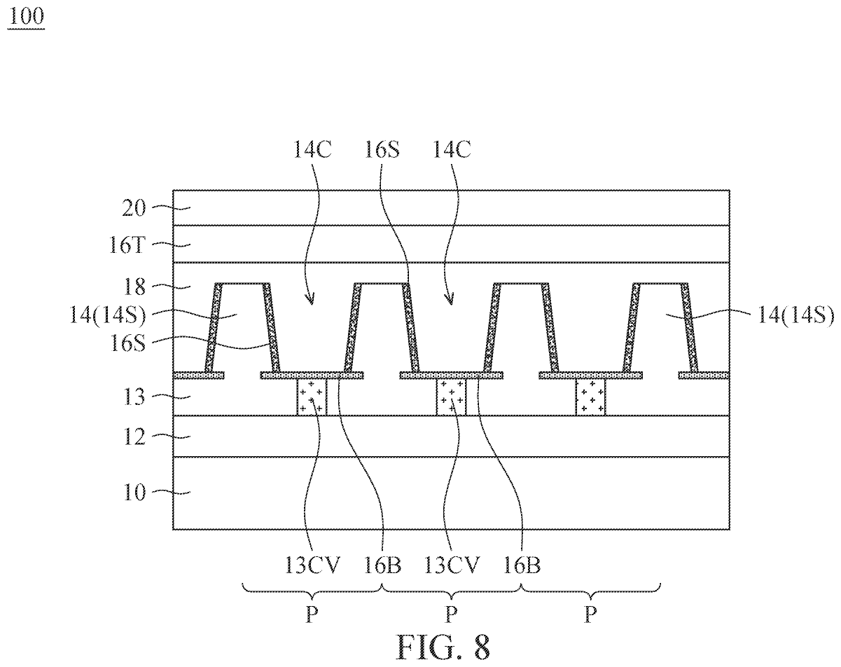

Referring to FIG. 8, in some embodiments, a top electrode 16T is formed on the photoelectric conversion layer 18. For example, the top electrode 16T may include the same or similar material as the bottom electrodes 16B, but the present disclosure is not limited thereto. The formation of the top electrode 16T may include using suitable deposition techniques, examples of which have been described above and will not be repeated here. Moreover, the top electrode 16T may be planarized with a planarization process, such as a chemical mechanical polishing (CMP) process, to form a substantially flat top surface, but the present disclosure is not limited thereto.

Then, as shown in FIG. 8, in some embodiments, an encapsulation layer 20 is formed on the top electrode 16T to form the image sensor 100. For example, the encapsulation layer 20 may include silicon nitride, silicon oxide, silicon oxynitride, aluminum oxide, any other applicable material, or a combination thereof. The formation of the encapsulation layer 20 may include using suitable deposition techniques, examples of which have been described above and will not be repeated here. Moreover, the encapsulation layer 20 may be planarized with a planarization process, such as a chemical mechanical polishing (CMP) process, to form a substantially flat top surface, but the present disclosure is not limited thereto.

As shown in FIG. 8, in some embodiments, the image sensor 100 includes a substrate 10 and an isolation structure 14 disposed over the substrate 10. The isolation structure 14 has isolation segments 14S in a cross-sectional view and is electrically non-conductive, and the isolation segments 14S form concave tanks 14C that define pixel regions P. The image sensor 100 also includes bottom electrodes 16B disposed at bottoms of the concave tanks 14C and reflective layers 16S disposed on sidewalls of the concave tanks 14C. The image sensor 100 further includes a photoelectric conversion layer 18 disposed on the isolation structure 14 and in the concave tanks 14C and a top electrode 16T disposed on the photoelectric conversion layer 18. Moreover, the image sensor 100 includes an encapsulation layer 20 disposed on the top electrode 16T.

In the embodiments of the present disclosure, optical cross-talk among pixels may be effectively improved duo to the reflective layers 16S on sidewalls of the concave tanks 14C. Moreover, charge carrier absorption in the photoelectric conversion layer 18 may also be increased duo to the reflective layers 16S on sidewalls of the concave tanks 14C, thereby increasing sensitivity of the image sensor 100.

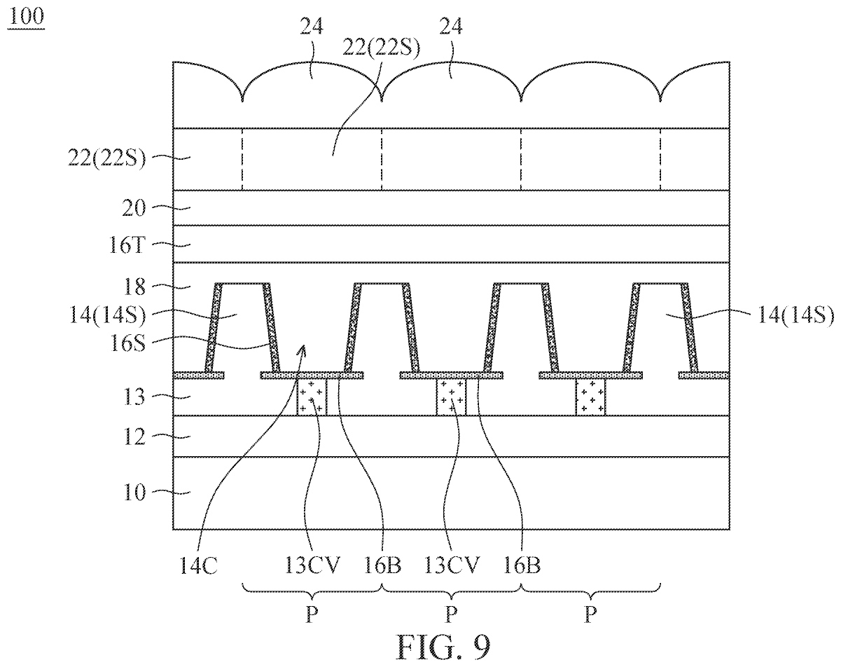

FIG. 9 is a cross-sectional view illustrating a portion of the image sensor 100 at additional stages in the manufacturing of the image sensor 100 in accordance with some other embodiments of the present disclosure. Similarly, some components of the image sensor 100 have been omitted in FIG. 9 for the sake of brevity.

Referring to FIG. 9, in some embodiments, condensing structures 24 are formed above the encapsulation layer 20, and each condensing structure 24 corresponds to one pixel region P. For example, the condensing structure 24 may include glass, epoxy resin, silicone resin, polyurethane, any other applicable material, or a combination thereof, but the present disclosure is not limited thereto. Moreover, the condensing structure 24 may be formed by a photoresist reflow method, a hot embossing method, any other applicable method, or a combination thereof. The steps of forming the condensing structure 24 may include a spin coating process, a lithography process, an etching process, any other applicable process, or a combination thereof, but the present disclosure is not limited thereto.

In some embodiments, the condensing structure 24 is a micro-lens for converging the incident light. For example, the micro-lens may include a semi-convex lens or a convex lens, but the present disclosure is not limited thereto. The condensing structure 24 may also include micro-pyramid structures (e.g., circular cone, quadrangular pyramid, and so on), or micro-trapezoidal structures (e.g., flat top cone, truncated square pyramid, and so on). Alternatively, the condensing structure 24 may be a gradient-index structure.

As shown in FIG. 9, in some embodiments, the image sensor 100 further includes a color filter layer 22 disposed between the encapsulation layer 20 and the condensing structures 24. In some embodiments, the color filter layer 20 has (or is divided into) color filter segments 22S in the cross-sectional view (e.g., cross-sectional view shown in FIG. 9), and the color filter segments 22S correspond to the concave tanks 14C and the pixel regions P.

In some embodiments, the color filter segments 22S capture different color information. For example, the color filter layer 22 may have a blue color filter segment, a green color filter segment, and/or a red color filter segment, but the present disclosure is not limited thereto. In some other examples, the color filter layer 22 may have a yellow color filter segment, a white color filter segment, a cyan color filter segment, a magenta color filter segment, or an IR/NIR color filter, but the present disclosure is not limited thereto.

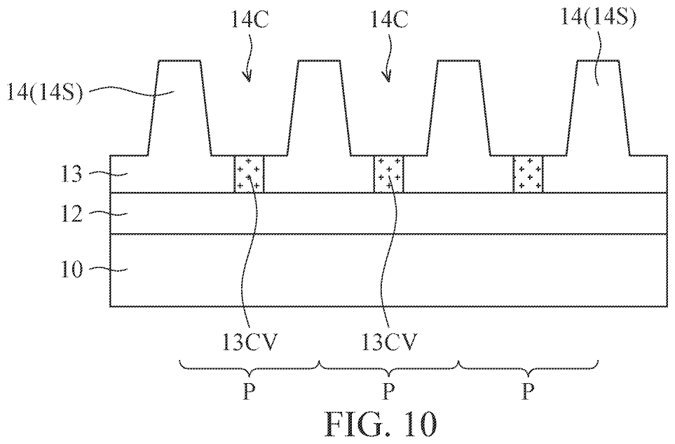

FIG. 10 to FIG. 12 are cross-sectional views illustrating a portion of the image sensor 100 at various stages in the manufacturing of the image sensor 100 in accordance with some other embodiments of the present disclosure. For example, the stages shown in FIG. 10 to FIG. 12 may replace the stages shown in FIG. 2 to FIG. 6. Similarly, some components of the image sensor 100 have been omitted in FIG. 10 to FIG. 12 for the sake of brevity.

Referring to FIG. 10, continuing from FIG. 1, in some embodiments, an isolation structure 14 is formed over the substrate 10, and the isolation structure 14 has (or is divided into) isolation segments 14S in a cross-sectional view (e.g. cross-sectional view shown in FIG. 10) and is electrically non-conductive. Moreover, as shown in FIG. 10, in some embodiments, the isolation segments 14S form concave tanks 14C that define pixel regions P. In more detail, the isolation structure 14 is formed directly on the isolation layer 13, and each contact vias 13CV is between two adjacent isolation segments 14S.

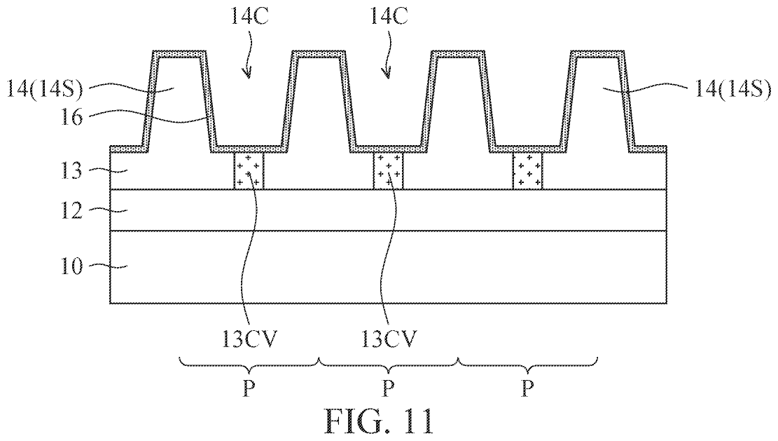

Referring to FIG. 11, in some embodiments, a cover layer 16 is formed on the isolation structure 14. As shown in FIG. 11, the cover layer 16 is disposed on the bottoms and sidewalls of the concave tanks 14C and the topmost surfaces (S14S) of the isolation structure 14 (the isolation segments 14S). For example, the cover layer 16 may include a conductive material, such as metal, metal silicide, the like, or a combination thereof, but the present disclosure is not limited thereto. The metal may include gold (Au), nickel (Ni), platinum (Pt), palladium (Pd), iridium (Ir), titanium (Ti), chromium (Cr), tungsten (W), aluminum (Al), copper (Cu), the like, an alloy thereof, or a combination thereof, but the present disclosure is not limited thereto. Moreover, the cover layer 16 may be formed by physical vapor deposition (PVD), chemical vapor deposition (CVD), atomic layer deposition (ALD), evaporation, sputtering, the like, or a combination thereof, but the present disclosure is not limited thereto.

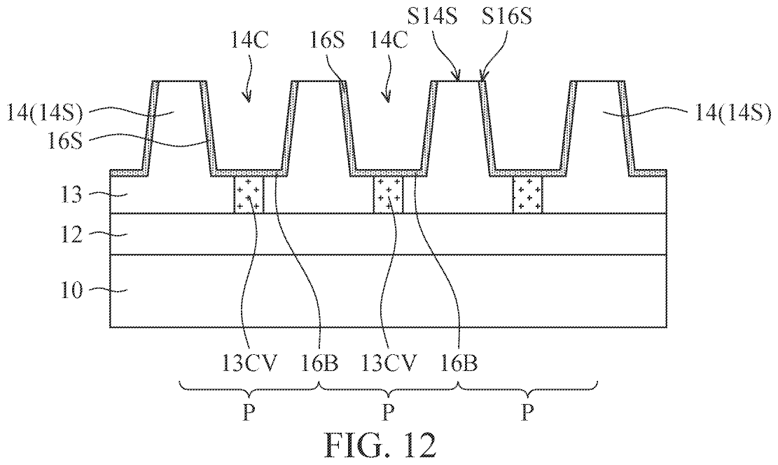

Referring to FIG. 12, in some embodiments, a portion of the cover layer 16 on the topmost surface S14S of the isolation structure 14 is removed to form bottom electrodes 16B at the bottoms of the concave tanks 14C and reflective layers 16S on the sidewalls of the concave tanks 14C. For example, the portion of the cover layer 16 on the topmost surface S14S of the isolation structure 14 may be removed by a chemical mechanical polishing (CMP) process, but the present disclosure is not limited thereto. In this embodiment, the reflective layers 16S include the same material as the bottom electrodes 16B.

As noted above, the image sensor according to the embodiments of the present disclosure includes reflective layers on sidewalls of the concave tanks of the isolation structure. Therefore, wide-angle incident light may be blocked in the concave tank to be transported into the corresponding pixel and may be prevented from reaching the neighbor pixel, thereby effectively improving optical cross-talk among pixels. Moreover, charge carrier absorption may be increased duo to the reflective layers on sidewalls of the concave tanks, thereby increasing sensitivity of the image sensor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. An image sensor, comprising:
a substrate;
an isolation structure disposed over the substrate, wherein the isolation structure has isolation segments in a cross-sectional view and is electrically non-conductive, and the isolation segments form concave tanks that define pixel regions;
bottom electrodes disposed at bottoms of the concave tanks;
reflective layers disposed on sidewalls of the concave tanks;
a photoelectric conversion layer disposed on the isolation structure and in the concave tanks;
a top electrode disposed on the photoelectric conversion layer; and
an encapsulation layer disposed on the top electrode.

2. The image sensor as claimed in claim 1, wherein the reflective layers comprise a conductive material.

3. The image sensor as claimed in claim 1, wherein the reflective layers comprise the same material as the bottom electrodes.

4. The image sensor as claimed in claim 1, wherein an included angle between each of the bottom electrodes and a corresponding one of the reflective layers in the cross-sectional view is between 90° and 135°.

5. The image sensor as claimed in claim 1, wherein a thickness of each of the reflective layers is greater than or equal to 20 nm.

6. The image sensor as claimed in claim 1, wherein a maximum width of each of the concave tanks in the cross-sectional view is greater than or equal to 100 nm.

7. The image sensor as claimed in claim 1, wherein a maximum width of each of the isolation segments in the cross-sectional view is greater than or equal to 100 nm.

8. The image sensor as claimed in claim 1, wherein a height of each of the isolation segments in the cross-sectional view is greater than or equal to 50 nm.

9. The image sensor as claimed in claim 1, wherein portions of the bottom electrodes extend into bottoms of the isolation segments.

10. The image sensor as claimed in claim 1, wherein a top surface of each of the reflective layers is aligned with or lower than a topmost surface of a corresponding one of the isolation segments.

11. The image sensor as claimed in claim 1, further comprising:
condensing structures disposed above the encapsulation layer, wherein each of the condensing structures corresponds to one of the pixel regions.

12. The image sensor as claimed in claim 11, further comprising:
a color filter layer disposed between the encapsulation layer and the condensing structures.

13. The image sensor as claimed in claim 12, wherein the color filter layer has color filter segments in the cross-sectional view, and the color filter segments correspond to the concave tanks.

14. The image sensor as claimed in claim 13, wherein the color filter segments capture different color information.

15. The image sensor as claimed in claim 1, further comprising:
a circuit layer disposed between the substrate and the isolation structure,
wherein the bottom electrodes are electrically connected to the circuit layer.

16. A method for forming an image sensor, comprising:
forming an isolation structure over a substrate, wherein the isolation structure has isolation segments in a cross-sectional view and is electrically non-conductive, and the isolation segments form concave tanks;
forming bottom electrodes at bottoms of the concave tanks;
forming reflective layers on sidewalls of the concave tanks;
forming a photoelectric conversion layer on the isolation structure and in the concave tanks;
forming a top electrode on the photoelectric conversion layer; and
forming an encapsulation layer on the top electrode.

17. The method for forming the image sensor as claimed in claim 16, wherein steps of forming the bottom electrodes and the reflective layers comprise:
forming a first conductive layer over the substrate;
patterning the first conductive layer to form the bottom electrodes and holes between the bottom electrodes; and
forming the isolation structure from the holes to form the concave tanks that define pixel regions.

18. The method for forming the image sensor as claimed in claim 17, wherein the steps of forming the bottom electrodes and the reflective layers further comprise:
forming a second conductive layer on the isolation structure; and
removing a portion of the second conductive layer on a topmost surface of the isolation structure to form the reflective layers on sidewalls of the concave tanks.

19. The method for forming the image sensor as claimed in claim 16, wherein steps of forming the bottom electrodes and the reflective layers comprise:
forming a cover layer on the isolation structure, wherein the cover layer is disposed on the bottoms and sidewalls of the concave tanks and a topmost surface of the isolation structure; and
removing a portion of the cover layer on the topmost surface of the isolation structure to form the bottom electrodes at the bottoms of the concave tanks and the reflective layers on the sidewalls of the concave tanks.

20. The method for forming the image sensor as claimed in claim 16, further comprising:
forming condensing structures above the encapsulation layer, wherein each of the condensing structures corresponds to one of the pixel regions.
